(19) United States
(12) Patent Application Publication
(10) Pub. No.: US 2019/0121235 A1
(43) Pub. Date: Apr. 25, 2019

(54) PHOTO-CURABLE AND THERMO-CURABLE RESIN COMPOSITION AND CURED PRODUCT THEREOF

(71) Applicant: SAMSUNG ELECTRO-MECHANICS CO., LTD., Suwon-si (KR)

(72) Inventors: Geum-Hee YUN, Suwon-si (KR); Hwa-Young LEE, Suwon-si (KR); Seol-Ah CHONG, Suwon-si (KR)

(73) Assignee: SAMSUNG ELECTRO-MECHANICS CO., LTD., Suwon-si (KR)

(21) Appl. No.: 15/983,787

(22) Filed: May 18, 2018

(30) Foreign Application Priority Data
Oct. 19, 2017 (KR) 10-2017-0135970

(51) Int. Cl. G03F 7/038; G03F 7/039; G03F 7/20; G03F 7/30; G03F 7/033; G03F 7/028; H01F 27/06; H05K 1/03; H05K 3/00

(52) U.S. Cl. CPC G03F 7/038; G03F 7/039; G03F 7/2004; G03F 7/3085; H05K 1/0237; G03F 7/028; H01F 27/06; H05K 1/0373; H05K 3/0011; G03F 7/033

(57) ABSTRACT

A photo-curable and thermo-curable resin composition includes an epoxy resin including an epoxy group; a carboxyl group-containing photosensitive resin; a photopolymerization initiator; and a filler, wherein a value of an equivalent number of the epoxy group/an equivalent number of the carboxyl group is from more than 1 to less than 2.

### CROSS-REFERENCE TO RELATED APPLICATIONS

This application claims the benefit under 35 USC § 119(a) of Korean Patent Application No. 10-2017-0135970 filed on Oct. 19, 2017, in the Korean Intellectual Property Office, the entire disclosure of which is incorporated herein by reference for all purposes.

### BACKGROUND

### 1. Field

This application relates to a photo-curable and thermo-curable resin composition and a cured product thereof.

### 2. Description of the Background

A multilayer build-up substrate or a high-frequency inductor substrate can be generally manufactured by the following process.

First, a film composed of a photosensitive resin composition is laminated on a substrate on which a circuit is formed. Then, a predetermined portion of the film is exposed to ultra violet (UV) light to be cured.

Next, the film is developed with an aqueous alkali solution to remove unexposed uncured portions, thereby forming an insulating layer composed of the cured product of the photosensitive resin composition on the substrate.

The cured product insulating layer is plated to form a via hole, and finally, a multilayer build-up substrate or a high-frequency inductor substrate is manufactured.

On the other hand, as a thickness of the interlayer insulating layer of a component element such as the multilayer build-up substrate or the high-frequency inductor substrate increases, a residue area of a bottom part of the via hole tends to increase. Further, when the photosensitive resin composition contains 60% or more of a filler, the greater the acid value, the faster the development speed, and the filler cannot be correspondingly developed together and removed as the residue.

Japanese Patent Publication No. 2011-227343 discloses a solder resist composition capable of forming a solder resist layer having high light reflectivity and a printed circuit board having a solder resist layer formed of the solder resist composition.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a photo-curable and thermo-curable resin composition includes an epoxy resin including an epoxy group; a carboxyl group-containing photosensitive resin; a photopolymerization initiator; and a filler, wherein a value of an equivalent number of the epoxy group/an equivalent number of the carboxyl group is from more than 1 to less than 2.

The photo-curable and thermo-curable resin composition may have an acid value of less than 30 mg KOH/g.

The photo-curable and thermo-curable resin composition may have a crosslink density (ρ) of 50×10³ mol/m³ to 150×10³ mol/m³ after curing.

The photo-curable and thermo-curable resin composition may have a glass transition temperature of 180° C. or higher after curing.

The photo-curable and thermo-curable resin composition may include 5 to 20 parts by weight of the epoxy resin, 20 to 25 parts by weight of the carboxyl group-containing photosensitive resin, 1 to 3 parts by weight of the photopolymerization initiator, and 60 or more parts by weight of the inorganic filler, wherein the parts by weight are based on the total weight of the photo-curable and thermo-curable resin composition.

The photo-curable and thermo-curable resin composition may further include 0.5 to 2 parts by weight of a photosensitive acrylate compound based on the total weight of the photo-curable and thermo-curable resin composition.

The photo-curable and thermo-curable resin composition may further include one or more of a pigment, a thickener, a defoaming agent, a leveling agent, and a silane coupling agent.

A dry film may include a dry layer of the photo-curable and thermo-curable resin composition on a carrier film.

A cured product may include the photo-curable and thermo-curable resin composition photo-cured and thermo-cured or in the dry film including the dry layer of the photo-curable and thermo-curable resin composition on the carrier film, photo-cured and thermo-cured.

The cured product may further include a via hole having a diameter of 55 μm or less.

A diameter of a lower surface of the via hole may be 80% or more of a diameter of an upper surface of the via hole.

A substrate may include the cured product.

The substrate may be a high-frequency inductor substrate.

In another general aspect, a method of making a substrate having a via hole, includes mixing an epoxy resin having an epoxy group, a carboxyl group-containing photosensitive resin, a photopolymerization initiator, and a filter to form a photo-curable and thermo-curable resin, wherein a value of an equivalent number of the epoxy group to an equivalent number of the carboxyl group is in a range from greater than 1 to less than 2, spreading the photo-curable and thermo-curable resin to form a product, and forming a via hole in the product.

In the method, forming the product may include one or more of coating a carrier film with the photo-curable and thermo-curable resin and drying the result, and photo-curing and thermo-curing the photo-curable and thermo-curable resin composition.

In the method, the via hole may have one or more of a diameter of 55 μm or less and a diameter of a lower surface of the via hole may be 80% or more of a diameter of an upper surface of the via hole.

In the method, the photo-curable and thermo-curable resin may include an acid value of less than 30 mg KOH/g.

In the method, the substrate may include a crosslink density (ρ) of from 50×10³ mol/m³ to 150×10³ mol/m³ after curing.

In the method, the substrate comprises a glass transition temperature of 180° C. or greater after curing.

In the method, the photo-curable and thermo-curable resin may include 5 to 20 parts by weight of the epoxy resin, 20 to 25 parts by weight of the carboxyl group-containing photosensitive resin, 1 to 3 parts by weight of the photopolymerization initiator, 60 or more parts by weight of the inorganic filler, and 0.5 to 2 parts by weight of a photosensitive acrylate compound, wherein the parts by weight are based on the total weight of the photo-curable and thermo-curable resin.

Other features and aspects will be apparent from the following detailed description, the drawings, and the claims.

### BRIEF DESCRIPTION OF THE DRAWINGS

FIG. 1 is a series of planar photographs of examples and comparative examples of via holes showing that residues of the via-holes are minimized.

FIG. 2 is a graph of data of via size and taper for examples and comparative examples illustrating increase of a percentage taper of bottom diameter/top diameter of the via hole.

FIG. 3 is a graph of data of glass transition temperature for examples and comparative examples illustrating an increase of a glass transition temperature of the examples of a cured product.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the compositions, methods, apparatuses, and/or systems described herein. However, various changes, modifications, and equivalents of the compositions, methods, apparatuses, and/or systems described herein will be apparent after an understanding of the disclosure of this application. For example, the features of the examples described herein may be combined in various ways as will be apparent after an understanding of the disclosure of this application. Further, although the examples described herein have a variety of configurations, other configurations are possible as will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the compositions, methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, or combinations thereof, but do not preclude the presence or addition of one or more other features, numbers, operations, members, elements, or combinations thereof.

Example embodiments of a curable resin composition described in this application reduce problems such as taper of a via hole and residues at a bottom of the via hole by controlling a value of a ratio of an equivalent number of an epoxy group/an equivalent number of a carboxyl group and a crosslink density. The example embodiments provide a photo-curable and thermo-curable resin composition capable of forming a cured product and a component element including an interlayer insulating layer formed with the composition.

An example photo-curable and thermo-curable resin composition according to a first embodiment includes an epoxy resin having an epoxy group, a carboxyl group-containing photosensitive resin, a photopolymerization initiator, and a filler, wherein a value of an equivalent number of the epoxy group/an equivalent number of the carboxyl group is from more than 1 to less than 2.

It is to be appreciated that the photo-curable and thermo-curable resin composition may have from more than 1 to less than 2 of the value of the equivalent number of the epoxy group/the equivalent number of the carboxyl group in order to minimize residues at the bottom part of via holes even if a thickness of an insulating layer increases. As a result, it is possible to form fine vias and fine pitches in a thin film substrate. However, the photo-curable and thermo-curable resin composition is not limited thereto. When the photo-curable and thermo-curable resin composition has 2 or higher of the value of the equivalent number of the epoxy group/the equivalent number of the carboxyl group, residues may be formed at the bottom of the via hole.

The example photo-curable and thermo-curable resin composition of the first embodiment has an acid value in a range from 10 mg KOH/g or higher to less than 30 mg KOH/g. For example, the acid value of the photo-curable and thermo-curable resin composition is 20 mg KOH/g or less, for example, 15 mg KOH/g or less. However, the photo-curable and thermo-curable resin composition is not limited thereto. When the acid value of the photo-curable and thermo-curable resin composition is less than 10 mg KOH/g, an alkaline developability may be deteriorated. On the other hand, when the acid value of the photo-curable and thermo-curable resin composition is 30 mg KOH/g or higher, a development speed at the time of development becomes faster and an inorganic filler may not be developed together with the other components of the photo-curable and thermo-curable resin composition.

Use of the example photo-curable and thermo-curable resin composition of the first embodiment described above can prevent offsets in the formation of via holes even when a large amount of filler is used, so that fine vias and fine pitches can be formed in the thin film substrate.

The example photo-curable and thermo-curable resin composition of the first embodiment has a crosslink density (ρ) of 50×10³ mol/m³ to 150×10³ mol/m³ after curing. However, the photo-curable and thermo-curable resin composition is not limited thereto.

When the crosslink density (ρ) of the photo-curable and thermo-curable resin composition is 50×10³ mol/m³ to 150×10³ mol/m³, a cured product having excellent modulus can be provided.

The example photo-curable and thermo-curable resin composition of the first embodiment has a glass transition temperature of 180° C. or higher after curing. However, the photo-curable and thermo-curable resin composition is not limited thereto.

When the glass transition temperature of the photo-curable and thermo-curable resin composition is 180° C. or higher after curing and the crosslink density (ρ) is 50×10³ mol/m³ to 150×10³ mol/m³, the modulus can be excellent even at a high temperature. Thus, use of the photo-curable and thermo-curable resin composition described herein allows not only forming a cured product with excellent thermal properties, but also providing an electronic component having high reliability at a high temperature.

The example photo-curable and thermo-curable resin composition of the first embodiment includes 5 to 20 parts by weight of an epoxy resin; 20 to 25 parts by weight of a carboxyl group-containing photosensitive resin; 1 to 3 parts by weight of a photopolymerization initiator; and 60 or more parts by weight of an inorganic filler, based on the total weight of the photo-curable and thermo-curable resin composition.

The example photo-curable and thermo-curable resin composition of the first embodiment further includes 0.5 to 2 parts by weight of a photosensitive acrylate compound based on the total weight of the photo-curable and thermo-curable resin composition.

The example photo-curable and thermo-curable resin composition of the first embodiment includes at least one chosen from a pigment, a thickener, a defoaming agent, a leveling agent, and a silane coupling agent.

Hereinafter, example components of the curable resin composition will be described in more detail.

Epoxy Resin

The example photo-curable and thermo-curable resin composition of the first embodiment includes an epoxy resin. The epoxy resin forms crosslinks with an acid-modified oligomer and the like, by thermal curing to ensure heat resistance or mechanical properties of a cured product.

The epoxy resin may be a conventionally known epoxy resin, for example a compound having two or more epoxy groups in the molecule, which is a multi-functional epoxy compound.

Examples of the multi-functional epoxy compound may include a bisphenol A type epoxy resin, a hydrogenated bisphenol A type epoxy resin, a brominated bisphenol A type epoxy resin, a bisphenol F type epoxy resin, a bisphenol S type epoxy resin, a novolak epoxy resin, a phenol novolac epoxy resin, a cresol novolak epoxy resin, a N-glycidyl epoxy resin, a bisphenol A novolac epoxy resin, a bixylenol epoxy resin, a biphenol epoxy resin, a chelate epoxy resin, a glyoxal epoxy resin, an epoxy resin having an amino group, a rubber-modified epoxy resin, a dicyclopentadiene phenolic epoxy resin, a diglycidyl phthalate resin, a heterocyclic epoxy resin, a tetraglycidylxylenoyl ethane resin, a silicone-modified epoxy resin, ε-caprolactone-modified epoxy resin and the like. Further, a phosphorus or another atom introduced into the structure may be used in order to impart flame retardancy. These epoxy resins improve the properties such as adhesion of a cured film, solder heat resistance, and electroless plating resistance by thermo-curing.

The epoxy resin may be added in an amount of 1 to 30 parts by weight, for example, 5 to 20 parts by weight based on the total weight of the photo-curable and thermo-curable resin composition. However, the photo-curable and thermo-curable resin composition is not limited thereto.

If the amount of the epoxy resin is less than 1 parts by weight, the carboxyl group may remain after the curing and thus, heat resistance, alkali resistance and electrical insulation may be deteriorated. On the other hand, if the amount exceeds 30 parts by weight, formation of fine vias becomes difficult due to the degradation of resolution, the probability of occurrence of residues increases, and the percentage of the diameter of the lower surface of the via hole/the diameter of the upper surface of the via hole may be reduced to less than 80%.

Carboxyl Group-Containing Photosensitive Resin

The example photo-curable and thermo-curable resin composition of the first embodiment includes a carboxyl group-containing photosensitive resin. The carboxyl group-containing photosensitive resin may be a conventionally known carboxyl group-containing photosensitive resin having a carboxyl group in the molecule for the purpose of imparting alkaline developability. For example, a carboxyl group-containing photosensitive resin having an ethylenically unsaturated double bond in a molecule can provide photo-curability and development resistance. The unsaturated double bonds can be derived from acrylic acid or methacrylic acid or derivatives thereof. However, the carboxyl group-containing photosensitive resin is not limited thereto. On the other hand, in the case of using only a carboxyl group-containing resin having no ethylenically unsaturated double bond, a photosensitive monomer having at least one ethylenically unsaturated group in the molecule can be used in order to make the composition be photo-curable.

Examples of the carboxyl group-containing photosensitive resin include the following compounds:

(1) a compound having an ethylenically unsaturated group such as a vinyl group, an allyl group, a (meth)acryloyl group and the like and a reactive group such as an epoxy group or an acid chloride in a part of a copolymer of (a) an unsaturated carboxylic acid such as (meth)acrylic acid and (b) a compound having an unsaturated double bond such as styrene, α-methyl styrene, lower alkyl(meth)acrylate, isobutylene, or the like, for example a carboxyl group-containing photosensitive resin prepared by reacting glycidyl(meth)acrylate and adding an ethylenically unsaturated group as a pendant.

(2) a carboxyl group-containing photosensitive resin prepared by reacting a copolymer of a compound (c) (e.g., glycidyl(meth)acrylate, α-methylglycidyl(meth)acrylate, etc.) having an epoxy group and an unsaturated double bond and a compound (b) having an unsaturated double bond with an unsaturated carboxylic acid (a), and then reacting the secondary hydroxyl group thus obtained with a saturated or unsaturated polybasic acid anhydride (d) for example, phthalic anhydride, tetrahydrophthalic anhydride, hexahydrophthalic anhydride, etc.

(3) a carboxyl group-containing photosensitive resin prepared by reacting a copolymer of an acid anhydride (e) for example, maleic anhydride, itaconic anhydride, etc., having an unsaturated double bond and a compound (b) having an unsaturated double bond with a compound (f) for example, hydroxyalkyl(meth)acrylate, etc., having one hydroxyl group and one or more ethylenically unsaturated double bond.

(4) a carboxyl group-containing photosensitive compound prepared by an esterification reaction (i.e., a complete or partial esterification reaction, for example, a complete esterification reaction) of an epoxy group of a below-mentioned multifunctional epoxy compound (g) having at least 2 epoxy groups per molecule or a multifunctional epoxy resin obtained from additionally epoxydizing the hydroxyl group of a multifunctional epoxy compound with epichlorohydrin and a carboxyl group of an unsaturated monocarboxylic acid (h) such as (meth)acrylic acid, and then further reacting the generated hydroxyl group with a saturated or unsaturated polybasic acid anhydride (d).

The carboxyl group-containing photosensitive resin may be added in an amount of 10 to 35 parts by weight, for example, 20 to 25 parts by weight based on the total weight of the photo-curable and thermo-curable resin composition. However, the photo-curable and thermo-curable resin composition is not limited thereto. When the amount of the carboxyl group-containing photosensitive resin is less than 10 parts by weight, the developability of the resin composition may be deteriorated and the residue may be increased. On the other hand, when the amount of the carboxyl group-containing photosensitive resin is more than 35 parts by weight, the photo-curable portion may be dissolved in the developing solution and reliability may be deteriorated.

Photopolymerization Initiator

The example photo-curable and thermo-curable resin composition of the first embodiment includes a photopolymerization initiator.

The photopolymerization initiator may be a conventionally known photopolymerization initiator including benzoin or alkyl ether thereof such as benzoin, benzoin methyl ether, benzoin ethyl ether and the like, an acetophenone such as acetophenone, 2,2-dimethoxy-2-phenylacetophenone, 1,1-dichloroacetophenone and 4-(1-t-butyldioxy-1-methylethyl)acetophenone, an anthraquinone such as 2-methyl anthraquinone, 2-amylanthraquinone, 2-t-butyl anthraquinone and 1-chloro anthraquinone, a thioxanthone such as 2,4-dimethylthioxanthone, 2,4-diisopropylthioxanthone and 2-chlorothioxanthone, a ketal such as acetophenone dimethyl ketal and benzyl dimethyl ketal, a benzophenone such as benzophenone, 4-(1-t-butyldioxy-1-methylethyl)benzophenone and 3,3′,4,4′-tetrakis(t-butyldioxycarbonyl) benzophenone and the like. However, the photopolymerization initiator is not limited thereto.

The photopolymerization initiator may be used in an amount of about 0.5 to 10 parts by weight, for example, 1 to 5 parts by weight, or even 1 to 3 parts by weight based on the total weight of the photo-curable and thermo-curable resin composition. However, the photo-curable and thermo-curable resin composition is not limited thereto. When the amount of the photo-initiator is too small, the photo-curing may not be performed properly. On the other hand, when the amount is excessively large, the resolution of the resin composition may be degraded or the reliability of the cured product may not be sufficient.

Filler

The example photo-curable and thermo-curable resin composition of the first embodiment includes a filler.

The filler may be an inorganic or an organic filler. The filler may be at least one chosen from barium sulfate, calcium carbonate, barium titanate, silicon oxide, silica, talc, clay, hydrotalcite, and mica powder. The inorganic filler may be silica. However, the filler is not limited thereto.

A particle size of the inorganic filler may be 50 nm to 3 μm, for example, 100 nm to 1 μm based on an equivalent diameter. However, the inorganic filler is not limited thereto. When the particle size of the inorganic filler is less than 50 nm, the mechanical strength may be lowered. On the other hand, when the particle size of the inorganic filler is more than 3 μm, the light transmittance may be lowered due to light scattering.

The filler may be used in an amount of about 50 or more parts by weight, for example, 60 or more parts by weight or higher based on the total weight of the photo-curable and thermo-curable resin composition. However, the photo-curable and thermo-curable resin composition is not limited thereto. When the amount of the filler is too small, the strength of the cured product is lowered. On the other hand, when the amount of the filler is too large, the viscosity of the resin composition becomes high and the coating property is deteriorated or the interfacial adhesion with the resin or circuit (metal) layer is significantly decreased. In addition, the cured product becomes brittle and thus can easily break or crack, make it difficult to handle, or degrade processability and reliability.

Photopolymerizable Monomer

The example photo-curable and thermo-curable resin composition according to the first embodiment includes a photopolymerizable monomer. The photopolymerizable monomer may be a compound having a photo-curable unsaturated functional group.

The photopolymerizable monomer may be liquid at room temperature, thereby adjusting the viscosity of the resin composition to be suitable for an application method, or enhancing the alkali developability of the unexposed portion.

The photopolymerizable monomer may be an acrylate compound having at least two photo-curable unsaturated functional groups. Examples of the photopolymerizable monomer may include an acrylate compound having hydroxyl group such as acrylate or methacrylate of pentaerythritol, acrylate or methacrylate of dipentaerythritol, a multifunctional polyester acrylate compound of polyhydric alcohol such as acrylate or methacrylate of trimethylolpropane, acrylate or methacrylate of pentaerythritol, and dipentaerythritol hexaacrylate, an acrylate compound of an ethylene oxide adduct and/or a propylene oxide adduct of a multifunctional alcohol such as hydrogenated bisphenol A or a polyhydric phenol such as bisphenol A and biphenol, a multifunctional or monofunctional polyurethane acrylate compound which is an isocyanate-modified product of the hydroxyl group-having acrylate, an epoxy acrylate compound which is a (meth)acrylic acid adduct of bisphenol A diglycidyl ether, hydrogenated bisphenol A diglycidyl ether or phenol novolac epoxy resin, a caprolactone-modified acrylate compound such as acrylate of ε-caprolactone-modified dipentaerythritol or caprolactone-modified acrylate compound, and a methacrylate compound corresponding to the above-mentioned acrylate compound. These compounds may be used alone or in combination of two or more.

For example, the photopolymerizable monomer may be a multifunctional (meth)acrylate compound having at least two (meth)acryloyl groups in one molecule, and as another example, pentaerythritol triacrylate, trimethylolpropane triacrylate, dipentaerythritol hexaacrylate, or caprolactone-modified ditrimethylolpropane tetraacrylate, or the like. An example of commercially available photopolymerizable monomer may include DPEA-12 from KAYARAD™ and the like.

The photopolymerizable monomer may be used in an amount of about 0.1 to 10 parts by weight, for example, about 0.5 to 5 parts by weight, or even about 0.5 to 2 parts by weight based on the total weight of the resin composition. If the amount of the photopolymerizable monomer is too small, the photo-curing may become insufficient. On the other hand, if the amount is excessively large, the drying of the cured product may be deteriorated and the physical properties may be thus deteriorated.

Pigment

The example photo-curable and thermo-curable resin composition of the first embodiment includes a pigment.

The pigment exhibits visibility and hiding power and hides defects such as scratches on circuit lines.

As the pigment used in the present description, all of the pigments satisfying the conditions according to the above description may be used. For example, both organic pigments and inorganic pigments can be used, and white pigments, black pigments and color pigments may be used alone or in combination.

An example of white pigment may be tin oxide.

Examples of black organic pigments may include one or more of perylene black, cyanine black, aniline black, and lactam black. Examples of the black inorganic pigment may include carbon black (lamp black, acetylene black, thermal black, channel black, furnace black and the like), chromium oxide, iron oxide, titanium black, titanium oxynitride, titanium nitride, strontium titanate, and ceria.

Examples of the color pigment, which can be used in combination with the black pigments, may include one or more of carmine 6B (C.I. 12490), phthalocyanine green (CI 74260), phthalocyanine blue (C.I. 74160), lionol yellow (C.I. 21090), lionol yellow GRO (CA. 21090), benzidine yellow 4T-564D, victoria pure blue (C.I. 42595), C.I. PIGMENT RED 97, 122, 149, 168, 177, 180, 192, 215, C.I. PIGMENT GREEN 7, 36, C.I. PIGMENT BLUE 15:1, 15:4, 15:6, 22, 60, 64, C.I. PIGMENT YELLOW 83, 139, C.I. PIGMENT VIOLET 23 and the like. Additionally, or alternatively, white pigments, fluorescent pigments and the like may also be used.

A content of the pigment is not limited thereto, but the pigment may be used in an amount of about 0.5 to 3 parts by weight based on the total weight of the photo-curable and thermo-curable resin composition. When the amount is less than 0.5 parts by weight, visibility and hiding power will be lowered. On the other hand, when the amount is more than 3 parts by weight, the resolution and thermal resistance of vias may be poor.

Additive

The example photo-curable and thermo-curable resin composition of the first embodiment includes an additive.

The additive may be added to remove bubbles of the resin composition, to remove popping or craters on the surface during film coating, to provide flame retardant properties, to control viscosity, to act as a catalyst, and the like.

Examples of the additives include a known thickener such as fine silica, organic bentonite, and montmorillonite, a defoaming agent and/or a leveling agent such as silicone, fluoride, and polymer, a silane coupling agent such as imidazole, thiazole and triazole, a flame retardant such as phosphorus flame retardant and antimony flame retardant, and the like.

For example, BYK-380N, BYK-307, BYK-378 and BYK-350 from BYK-CHEMIE™ GmbH can be used as the leveling agent in removing the popping or craters on the surface during film coating.

An amount of the additive may be about 0.01 to 10 parts by weight based on the total weight of the photo-curable and thermo-curable resin composition.

According to a second embodiment of this disclosure, an example dry film is obtained by applying and drying a photo-curable and thermo-curable resin composition onto a carrier film. In the dry film of the second embodiment, the photo-curable and thermo-curable resin composition can be the example photo-curable and thermo-curable resin composition of the first embodiment.

According to a third embodiment of this disclosure, an example cured product is prepared by photo-curing and thermo-curing a photo-curable and thermo-curable resin composition or a dry film prepared by coating a photo-curable and thermo-curable resin composition on a carrier film and drying the result. In the third embodiment, the photo-curable and thermo-curable resin composition can be the example photo-curable and thermo-curable resin composition of the first embodiment and the dry film can be the example dry film of the second embodiment.

The cured product may have a thickness of 1 to 30 μm. Further, it is possible to form fine vias and fine pitches even in a thin film substrate of the cured product of the third embodiment.

The cured product may have a via hole having a diameter of 55 μm or less. Further, it is possible to form fine vias and fine pitches in the cured product of the third embodiment.

A percentage of the diameter of the lower surface of the via hole/the diameter of the upper surface of the via hole may be 80% or higher. A via hole similar to a vertical shape can be formed by controlling the offset.

According to a fourth embodiment of this disclosure, an example substrate includes the cured product. In the fourth embodiment, the cured product can be the example cured product of the third embodiment.

According to the first through fourth embodiments of this disclosure, by using the resin composition, a pattern of a cured film having excellent properties such as sensitivity, resolution, and heat resistance can be formed, and a multilayer build-up substrate and a high-frequency inductor substrate can be provided.

An example process of manufacturing a dry film solder resist (SR) according to a fifth embodiment uses a photo-curable and thermo-curable resin composition described above in the first through fourth embodiments as follows.

A curable resin composition, for example, as described above in the first embodiment, is applied as a photosensitive coating material to a carrier film by a comma coater, a blade coater, a lip coater, a rod coater, a squeeze coater, a reverse coater, a transfer roll coater, a spray coater or the like, and the result is dried by passing through an oven at a temperature of 50 to 130° C. for 1 to 30 minutes. A release film is laminated thereon to form a dry film which is thus composed of a carrier film, a photosensitive film, and a release film from the bottom.

After the release film is peeled off, the dry film is bonded to a circuit-formed substrate using a vacuum laminator, a hot roll laminator, a vacuum press, or the like.

The substrate is exposed by a light ray (UV or the like) having a certain wavelength band. The exposure may be performed with a photomask for selective patterning, or may be performed with a laser direct exposure apparatus for direct patterning. The carrier film is peeled off after the exposure. The exposure dose varies depending on the coating film thickness, but is, for example, more than 0 to 1,000 mJ/cm². When the exposure is continued, for example, photo-curing occurs in the exposed portion, and cross-linking can be formed between the carboxyl group-containing photosensitive resin and the unsaturated functional groups contained in the photosensitive monomer, and as a result, it can be left unremoved by subsequent development. On the other hand, the unexposed portion can be alkali-developable by maintaining the carboxyl group without forming the crosslinking and the crosslinking structure formed thereby.

Development is then performed using an alkali solution or the like. The alkali solution may be an aqueous alkali solution such as potassium hydroxide, sodium hydroxide, sodium carbonate, potassium carbonate, sodium phosphate, sodium silicate, ammonia, amines, and the like. By this development process, only the film of the exposed portion can remain.

Finally, the printed circuit board including the solder resist formed from the photosensitive film is provided by thermo-curing (Post Cure). The thermo-curing temperature is, for example, 100° C. or higher.

The dry film solder resist may be used as a protective film for the printed circuit board.

The dry film solder resist may be used for manufacturing a package substrate of a semiconductor device. In particular, the solder resist may be used for an outermost layer for external impact protection or may replace an existing film or polypropylene glycol (PPG) to be used as an interlayer insulating layer of internal multilayer build-up substrate (particularly, an insulating layer for high frequency inductor) since it does not remain in the final product.

This is possible because the dry film solder resist contains enough inorganic filler (silica) about 50 or more parts by weight based on the total weight, so it has sufficient rigidity to prevent warping, and the dry film solder resist allows to form fine vias and cope with high density fine circuits and facilitates handling and processing by being processed in film form instead of liquid.

Hereinafter, examples of the embodiments of this disclosure that have been reduced to practice in the laboratory together with comparative examples will be described in detail. However, this disclosure is not limited to or limited by the following examples.

### EXAMPLES AND COMPARATIVE EXAMPLES: PREPARATION OF RESIN COMPOSITION AND DRY FILM SOLDER RESIST

The resin compositions of Examples 1 and 2 and Comparative Examples 1 to 3 were prepared by mixing the components shown in Table 1 below.

Using this composition, a 15 μm-thick film was prepared by hand casting.

In order to verify a via resolution of the prepared film, the film was V-laminated twice to a CZ-treated (surface roughened) copper-clad laminate (CCL). The lamination temperature was set at about 60 to 100° C.

Thereafter, an ultraviolet-direct imaging (UV-DI) equipment was used to expose in an amount of 200 to 400 mJ without offsets.

A development process was carried out to remove unexposed portions and developed for 80 to 150 seconds using a vertical developing machine.

TABLE 1

| | Examples | | Comparative Examples | | |
|---|---|---|---|---|---|
| | #1 | #2 | #1 | #2 | #3 |
| Epoxy/COOH | 1.2 | 1.67 | 1 | 2 | 2 |
| equivalence ratio | | | | | |
| Epoxy | 10% | 12% | 9% | 12% | 14% |
| Silica | 63% | 63% | 63% | 63% | 63% |
| Acid-acrylate (Binder) | 23% | 21% | 25% | 21% | 19% |
| Acrylate | 1% | 1% | 1% | 0% | 1% |
| photoinitiator | 2% | 2% | 2% | 3% | 2% |
| Pigment and | 1% | 1% | 1% | 1% | 1% |
| other additives | | | | | |
| Residues | No | No | No | Yes | Yes |
| Taper, % | 82 | 84 | 80 | 80 | 76 |
| Tg, ° C. | 186 | 191 | 124 | 150 | 204 |
| Crosslink density | 80 | 92 | 31 | 41 | 107 |
| p, kmol/m3 | | | | | |
| Acid value, mgKOH/g | 10.2 | 13.5 | 17.1 | 15.85 | 17.27 |

### Comparative Example 1

A resin composition and a dry film solder resist were prepared in the same manner as in Example 1, except that the equivalence ratio of the epoxy group and the carboxyl group was 1.

### Comparative Example 2

A resin composition and a dry film solder resist were prepared in the same manner as in Example 1, except that the equivalence ratio of the epoxy group and the carboxyl group was 2 and the photopolymerizable monomer was excluded.

### Comparative Example 3

A resin composition and a dry film solder resist were prepared in the same manner as in Example 1, except that the equivalence ratio of the epoxy group and the carboxyl group was 2.

The properties of the dry film solder resists prepared in Examples and Comparative Examples were measured by the following methods. The results are shown in Table 1.

(1) Residue of Filler

The solder resist compositions of Examples 1 and 2 and Comparative Examples 1 to 3 were cast into films, vacuum laminated on the copper foil substrates, and dried in a hot air circulation type drying furnace at 60 to 100° C. for 1 to 3 minutes. The result was developed with a 1 mass % Na₂CO₃ aqueous solution having a spray pressure of 0.2 MPa for 2 minutes, and the developability of the surface of the coating film was evaluated according to the following criteria.

◯: Coating is completely removed and no residue is left.

Δ: Very minimal filler residue is left

X: Residue is left

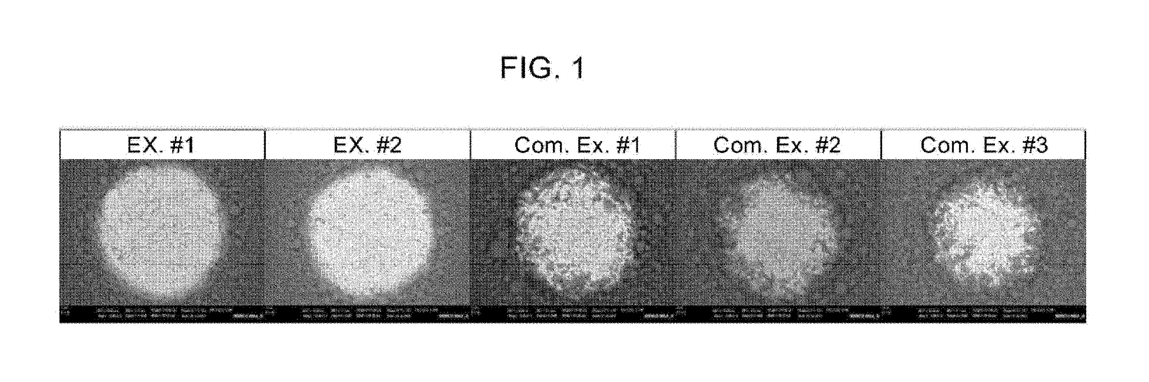

FIG. 1 is series of planar photographs of examples and comparative examples of via holes showing that residues of the via-holes are minimized.

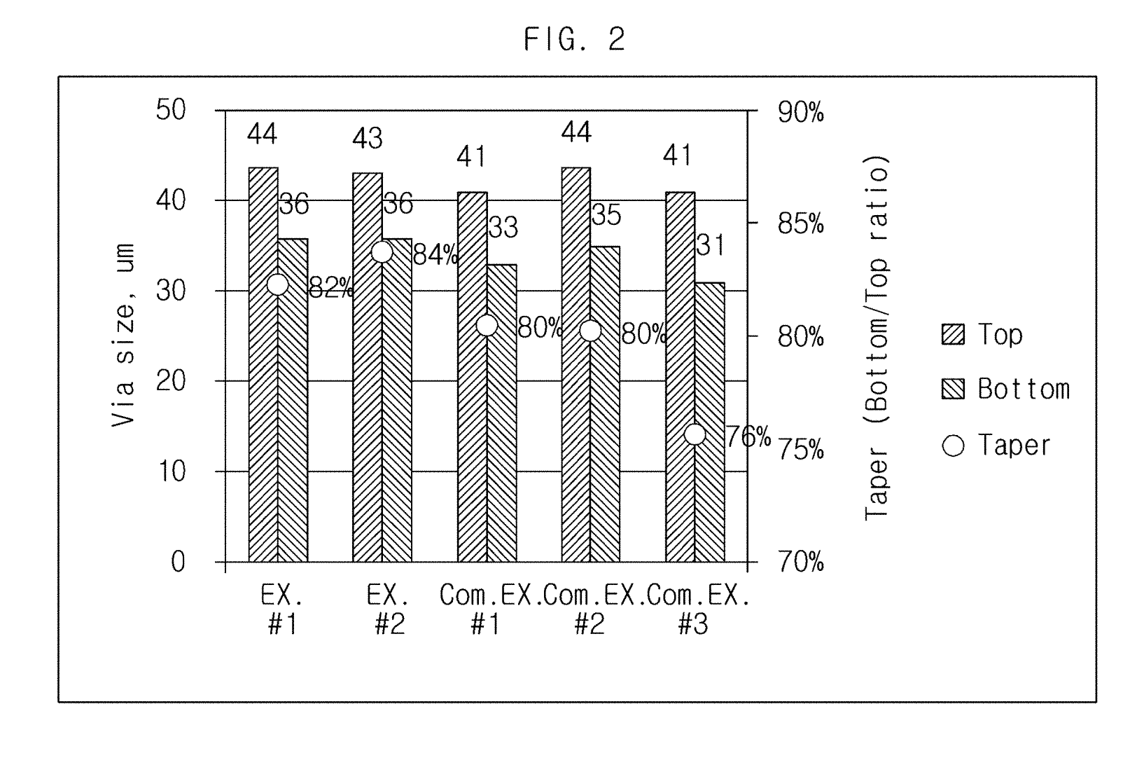

FIG. 2 is a graph of data of via size and taper for examples and comparative examples illustrating increase of a percentage taper of bottom diameter/top diameter of the via hole.

According to the example embodiments of this disclosure, a vertical via hole having no offset and no undercut can be formed.

(2) Crosslink Density and Glass Transition Temperature

Samples to be measured were prepared from the films prepared by casting the compositions of Examples 1, 2 and Comparative Examples 1 to 3, and set in the measuring apparatus.

Measuring device/manufactured by TA INSTRUMENTS™.

Format: Q800.

Measurement condition/Measurement temperature: 20 to 300° C.

Heating rate: 5° C./min.

Frequency: 1 Hz.

Deformation mode: Tensile mode.

Measured film size: 20 mm L×5 mm W.

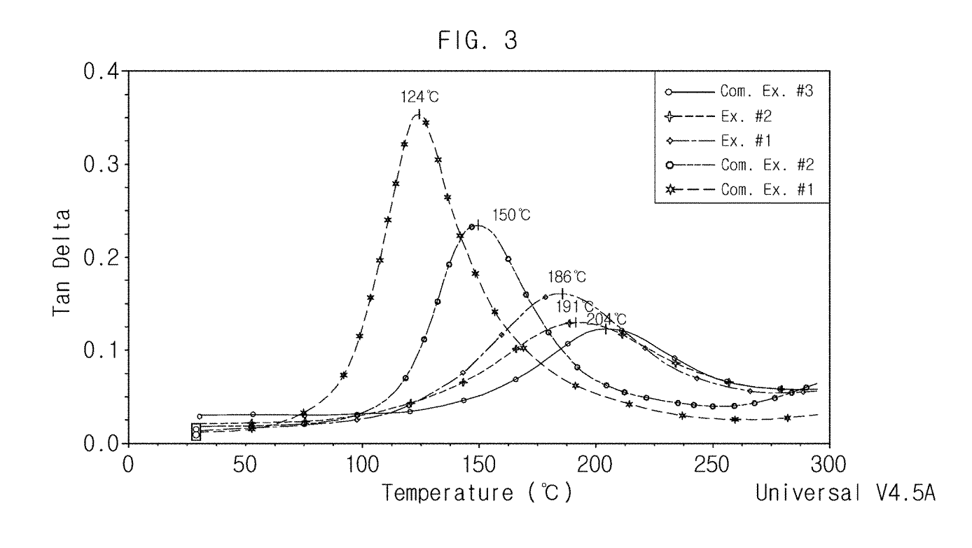

E′ (storage elastic modulus), E″ (loss elastic modulus) were determined by the dynamic viscoelasticity test according to the test method described in JIS K7244-4 and the crosslinking density (ρ) and the glass transition temperature (Tg) were measured therefrom according to the following Equation (1). The results are shown in Table 1 and FIG. 3.

ρ=E′min/3ϕRT Equation 1

where ρ is crosslink density (mol/m³), E′min is the minimum value of storage elastic modulus E′(N/m²), ϕ is the front coefficient approximately equal to 1, R is the gas constant (N·m/mol·K), T is the absolute temperature (K) of E′min.

FIG. 3 is a graph of data of glass transition temperature for examples and comparative examples illustrating an increase of a glass transition temperature of the examples of a cured product.

The Examples and Comparative Examples and the analysis thereof as set forth herein confirms that a pattern of a cured coating having excellent characteristics such as sensitivity, resolution, adhesion, heat resistance, and chemical resistance can be formed by using the photo-curable and thermo-curable resin composition of this disclosure.

Use of the curable resin composition described in this application allows minimizing residues at the bottom part of via holes even if a thickness of an insulating layer increases, so that fine vias and fine pitches can be formed in a thin film substrate.

Use of the curable resin composition described in this application further allows preventing offsets in the formation of via holes even with a large amount of filler, so that fine vias and fine pitches can be formed in the thin film substrate.

Use of the curable resin composition described in this application further allows forming a cured product with excellent thermal properties.

Use of the curable resin composition described in this application still further allows forming a pattern of hardened film having excellent properties such as sensitivity, resolution, and heat resistance, so that a multilayer build-up substrate and a high-frequency inductor substrate with a highly reliability can be provided.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, composition, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A photo-curable and thermo-curable resin composition comprising:
an epoxy resin comprising an epoxy group;
a carboxyl group-containing photosensitive resin;
a photopolymerization initiator; and
a filler,
wherein a value of an equivalent number of the epoxy group/an equivalent number of the carboxyl group is from more than 1 to less than 2.

2. The photo-curable and thermo-curable resin composition of claim 1, comprising an acid value of less than 30 mg KOH/g.

3. The photo-curable and thermo-curable resin composition of claim 1, comprising a crosslink density (ρ) of from 50×10³ mol/m³ to 150×10³ mol/m³ after curing.

4. The photo-curable and thermo-curable resin composition of claim 1, comprising a glass transition temperature of 180° C. or higher after curing.

5. The photo-curable and thermo-curable resin composition of claim 1, comprising:
5 to 20 parts by weight of the epoxy resin;
20 to 25 parts by weight of the carboxyl group-containing photosensitive resin;
1 to 3 parts by weight of the photopolymerization initiator; and
60 or more parts by weight of the inorganic filler,
wherein the parts by weight are based on the total weight of the photo-curable and thermo-curable resin composition.

6. The photo-curable and thermo-curable resin composition of claim 1, further comprising 0.5 to 2 parts by weight of a photosensitive acrylate compound based on the total weight of the photo-curable and thermo-curable resin composition.

7. The photo-curable and thermo-curable resin composition of claim 1, further comprising one or more of a pigment, a thickener, a defoaming agent, a leveling agent, and a silane coupling agent.

8. A dry film comprising a dry layer of the photo-curable and thermo-curable resin composition of claim 1 on a carrier film.

9. A product comprising the photo-curable and thermo-curable resin composition of claim 1 photo-cured and thermo-cured or in a dry film photo-cured and thermo-cured comprising a dry layer of the photo-curable and thermo-curable resin composition on a carrier film.

10. The product of claim 9, further comprising a via hole comprising a diameter of 55 μm or less.

11. The product of claim 10, wherein a diameter of a lower surface of the via hole is 80% or more of a diameter of an upper surface of the via hole.

12. A substrate comprising the product of claim 9.

13. The substrate of claim 12, wherein the substrate is a high-frequency inductor substrate.

14. A method of making a substrate comprising a via hole, comprising:
mixing an epoxy resin comprising an epoxy group, a carboxyl group-containing photosensitive resin, a photopolymerization initiator, and a filter to form a photo-curable and thermo-curable resin, wherein a value of an equivalent number of the epoxy group to an equivalent number of the carboxyl group is in a range from greater than 1 to less than 2;
spreading the photo-curable and thermo-curable resin to form a product; and
forming a via hole in the product.

15. The method of claim 14, wherein forming the product comprises one or more of:
coating a carrier film with the photo-curable and thermo-curable resin and drying the result; and
photo-curing and thermo-curing the photo-curable and thermo-curable resin composition.

16. The method of claim 14, wherein the via hole comprises one or more of a diameter of 55 μm or less and a diameter of a lower surface of the via hole is 80% or more of a diameter of an upper surface of the via hole.

17. The method of claim 14, wherein the photo-curable and thermo-curable resin comprises an acid value of less than 30 mg KOH/g.

18. The method of claim 14, wherein the substrate comprises a crosslink density (ρ) of from 50×10³ mol/m³ to 150×10³ mol/m³ after curing.

19. The method of claim 14, wherein the substrate comprises a glass transition temperature of 180° C. or greater after curing.

20. The method of claim 14, wherein the photo-curable and thermo-curable resin comprises:
5 to 20 parts by weight of the epoxy resin;
20 to 25 parts by weight of the carboxyl group-containing photosensitive resin;
1 to 3 parts by weight of the photopolymerization initiator;
60 or more parts by weight of the inorganic filler; and
0.5 to 2 parts by weight of a photosensitive acrylate compound,
wherein the parts by weight are based on the total weight of the photo-curable and thermo-curable resin.
